(19) United States
(12) Patent Application Publication
(10) Pub. No.: US 2011/0147073 A1
(43) Pub. Date: Jun. 23, 2011

(54) ELECTROMAGNETIC RADIATION ABSORBER AND METHOD FOR ABSORBING ELECTROMAGNETIC RADIATION

(75) Inventors: Katsuya Kume, Ibaraki-shi (JP); Masataka Tada, Ibaraki-shi (JP); Fuyuki Eriguchi, Ibaraki-shi (JP); Takezo Hatanaka, Ibaraki-shi (JP); Yuuki Fukuda, Ibaraki-shi (JP); Toshinobu Hoshino, Ibaraki-shi (JP); Osamu Hashimoto, Sagamihara-shi (JP); Yuichi Sakumo, Sagamihara-shi (JP)

(73) Assignee: NITTO DENKO CORPORATION, Ibaraki-shi, Osaka (JP)

(21) Appl. No.: 12/673,291

(22) PCT Filed: Sep. 19, 2008
(86) PCT No.: PCT/JP2008/066978

§ 371 Date: Mar. 8, 2010

(30) Foreign Application Priority Data
Sep. 20, 2007 (JP) 2007-243749

(51) Int. Cl. H05K 9/00

(52) U.S. Cl. 174/391

(57) ABSTRACT

An electromagnetic radiation absorber is made up of a composite of base material and filler. The base material is formed of high permittivity dielectric material and formed in a cubic shape. The filler is formed of high magnetic permeability material and fills in long holes formed inside the base material in three directions. In the composite, the high permittivity dielectric material and the high magnetic permeability material are arranged in a three-dimensionally continuous manner. Accordingly, a thinned and light-weighted electromagnetic radiation absorber and a method for absorbing electromagnetic radiation are provided which have a high electromagnetic radiation absorbing property with respect to electromagnetic radiation of wide band including electromagnetic radiation of low frequency.

### TECHNICAL FIELD

The present invention relates to an electromagnetic radiation absorber and a method for absorbing electromagnetic radiation which make it possible to absorb wideband electromagnetic radiation emitted from electronic components such as motors.

### BACKGROUND ART

Recently there have been not a few cases where electromagnetic radiation emitted from electronic devices such as driving motors and computers disturbs normal operation of other electronic devices. Accordingly, countermeasures are conventionally taken to prevent ill effects from the electromagnetic radiation, through surrounding such an electronic device or forming a dividing wall with an absorber that absorbs electromagnetic radiation (refer to Japanese Laid-Open Patent Application 2004-207328, for instance). In such an electromagnetic radiation absorber, it is important to take in incident electromagnetic radiation to the inside of the absorber without reflection as well as to attenuate the incident electromagnetic radiation, as a requirement to improve an electromagnetic radiation absorbing property.

Conventionally, the following electromagnetic radiation absorbers have been used.

One type is an electromagnetic radiation absorber that utilizes a conditional expression for no-reflection wherein the electromagnetic radiation absorber is brought into a no-reflection state at the surface of the absorber. In the electromagnetic radiation absorber that utilizes the conditional expression for no-reflection, for instance, an electromagnetic radiation reflective metal film is provided with dielectrics arranged at regular intervals (for instance, λ/4) on the surface thereof, and then is overlaid with an electromagnetic radiation absorption film. Reflection waves of the electromagnetic radiation can be reduced by matching impedances so that a surface reflection wave that is reflected from the surface of the electromagnetic radiation absorption film and an internal reflection wave that is reflected inside the absorber are in antiphase when electromagnetic radiation is incident thereon.

However, the electromagnetic radiation absorber that utilizes the above conditional expression for no-reflection has an excellent electromagnetic radiation absorbing property with respect to electromagnetic radiation of specific narrow-band frequency, but with respect to electromagnetic radiation of other band of frequency, the electromagnetic radiation absorbing property thereof is unsatisfactory.

Meanwhile, there are electromagnetic radiation absorbers of a wedge structure and a pyramidal structure among electromagnetic radiation absorbers where an electromagnetic radiation absorbing property can be obtained with respect to electromagnetic radiation of wideband frequency. The electromagnetic radiation absorbers of such structures are, for instance, used in the walls of radio-frequency anechoic chambers. The volume ratio of absorbent material in a space increases as going deeper into the wall thickness from the front face of such an absorber of the wedge structure or the pyramidal structure. Thus, the electromagnetic radiation absorbers can improve the property of absorbing electromagnetic radiation in case electromagnetic radiation is incident on the front face of the absorbers, thereby reducing reflection waves.

However, an electromagnetic radiation absorber having a wedge structure or a pyramidal structure requires extreme thickness (for instance, several meters) in order to expand its electromagnetic radiation absorbing property so as to be applicable to electromagnetic radiation of low frequency (MHz band). (Refer to Japanese Laid-Open Patent Application 2004-207328, pages 3 to 4 and FIG. 1)

### DISCLOSURE OF THE INVENTION

### Problems to be Solved by the Invention

Here, in recent years, various sensors such as a speed sensor installed in a car body have had a problem of malfunction caused by electromagnetic radiation emitted from driving motors or batteries in a hybrid vehicle. However, when a sheet of the electromagnetic radiation absorber that utilizes the above conditional expression for no-reflection is used for absorbing such electromagnetic radiation, there has been a problem that the sheet becomes extremely thick particularly if electromagnetic radiation of low frequency is the target for the absorption. Further, the use of the above electromagnetic radiation absorber of the wedge structure or the pyramidal structure is impractical in such a limited space like a car body.

The present invention has been worked out to overcome the above problems and the object thereof is to provide a novel electromagnetic radiation absorber and a method for absorbing electromagnetic radiation, which have a high electromagnetic radiation absorbing property with respect to the electromagnetic radiation of wideband including that of low frequency, and which can be made into a thin film and can reduce the weight.

### Means for Solving the Problem

To achieve the above object of the disclosure, there is provided an electromagnetic radiation absorber. The electromagnetic radiation absorber comprises a composite of high permittivity dielectric material and high magnetic permeability material. In the composite, the high permittivity dielectric material and the high magnetic permeability material are arranged in a three-dimensionally continuous manner.

To achieve the above object of the disclosure, there is provided a electromagnetic radiation absorber according to claim 1. The electromagnetic radiation absorber comprises base material made up of one of the high permittivity dielectric material and the high magnetic permeability material, the base material including therein a plurality of long holes; and filler made up of other one of the high permittivity dielectric material and the high magnetic permeability material, the filler being configured to fill in the plurality of long holes. The plurality of long holes includes a first long hole formed in a predetermined direction, a second long hole intersecting with the first long hole, and a third long hole intersecting with the first long hole and the second long hole.

To achieve the above object of the disclosure, there is provided a electromagnetic radiation absorber according to claim 1. The electromagnetic radiation comprises a first cord-shaped member formed of the high permittivity dielectric material; and a second cord-shaped member formed of the high magnetic permeability material. Plurality of the first cord-shaped member and plurality of the second cord-shaped member are intermingled.

To achieve the above object of the disclosure, there is provided a electromagnetic radiation absorber according to any one of claims 1 to 3. The electromagnetic radiation comprises the conductive material which is added to the high permittivity dielectric material.

Further, to achieve the above object of the disclosure, there is provided an electromagnetic radiation absorbing method. The electromagnetic radiation absorbing method is a method for absorbing electromagnetic radiation incident on the high permittivity dielectric material and the high magnetic permeability material, the method utilizing an electromagnetic radiation absorber including high permittivity dielectric material and high magnetic permeability material.

The method comprises bringing a first reflection wave that is reflection of the electromagnetic radiation incident on the high permittivity dielectric material and a second reflection wave that is reflection of the electromagnetic radiation incident on the high magnetic permeability material into opposite phase to each other, thereby cancelling out the first reflection wave and the second reflection wave.

### EFFECT OF THE INVENTION

According to a first aspect of the invention, in the electromagnetic radiation absorber, high permittivity dielectric material and high magnetic permeability material are arranged in a continuous structure even in a direction of oscillation of magnetic field components or electric field components of the electromagnetic radiation. Accordingly, a magnetic circuit and an electric circuit are not disrupted, and thus the electromagnetic radiation absorber has a high electromagnetic radiation absorbing property to the electromagnetic radiation of wideband frequencies including that of low frequency. In addition, even when the electromagnetic radiation absorber is made into a thin sheet, the sheet still maintains the high electromagnetic radiation absorbing property. Accordingly the electromagnetic radiation absorber can be used for wider purposes.

According to a second aspect of the invention, the electromagnetic radiation absorber has a simple structure for forming a composite of high permittivity dielectric material and high magnetic permeability material arranged in a three-dimensionally continuous manner to each other, thereby enabling easy manufacture and ensuring excellent productivity thereof.

According to a third aspect of the invention, the electromagnetic radiation absorber has a simple structure for forming a composite of high permittivity dielectric material and high magnetic permeability material arranged in a three-dimensionally continuous manner to each other, thereby enabling easy manufacture and ensuring excellent productivity thereof.

According to another aspect of the invention, the value of an imaginary part of complex relative permittivity of the electromagnetic radiation absorber can be largely increased and be controlled. Accordingly, by adjusting the type and amount of conductive material to add, it becomes possible to make an imaginary part μᵣ″ of complex relative permeability equal to a term (∈ᵣ″+σ/ω) including an imaginary part of complex relative permittivity, and also to make the characteristic impedance of the electromagnetic radiation absorber equal to the characteristic impedance of air. As a result, electromagnetic radiation incident on the electromagnetic radiation absorber is not reflected from the surface of the electromagnetic radiation absorber, but can entirely enter the electromagnetic radiation absorber.

According to a fifth aspect of the invention, the electromagnetic radiation absorbing method can cancel out the reflection wave through bringing the first reflection wave with respect to the incident electromagnetic radiation to the high permittivity dielectric material included in the electromagnetic radiation absorber and the second reflection wave with respect to the incident electromagnetic radiation to the high magnetic permeability material included in the electromagnetic radiation absorber into opposite phase to each other, thereby enabling the attenuation of the reflection wave reflected from the surface of the electromagnetic radiation absorber.

### BRIEF DESCRIPTION OF THE DRAWINGS

FIG. 1 is an explanatory view depicting an electromagnetic radiation absorber according to a first embodiment;

FIG. 2 is a view depicting an electromagnetic radiation absorbing sheet manufactured by mixing high permittivity dielectric material, high magnetic permeability material and conductive material in particle level;

FIG. 3 is a view depicting an incident wave and a reflection wave when electromagnetic radiation is incident on base material (high permittivity dielectric material) included in the electromagnetic radiation absorber according to the first embodiment;

FIG. 4 is a view depicting an incident wave and a reflection wave when electromagnetic radiation is incident on filler (high magnetic permeability material) included in the electromagnetic radiation absorber according to the first embodiment;

FIG. 5 is a view depicting an incident wave and reflection waves when electromagnetic radiation is incident on the electromagnetic radiation absorber according to the first embodiment;

FIG. 6 is a view depicting an electromagnetic radiation absorbing property of the electromagnetic radiation absorber according to the first embodiment;

FIG. 7 is an explanatory view depicting an electromagnetic radiation absorber according to a second embodiment;

FIG. 8 is an explanatory view depicting an electromagnetic radiation absorber according to a third embodiment with a partial enlargement;

FIG. 9 is an explanatory view depicting an electromagnetic radiation absorber according to a fourth embodiment with a partial enlargement;

FIG. 10 is an explanatory view depicting an electromagnetic radiation absorber according to a fifth embodiment with a partial enlargement;

FIG. 11 is a diagram depicting a measured result of a real part μᵣ′ of complex relative permeability and a real part ∈ᵣ′ of complex relative permittivity with respect to sample 1 and sample 2;

FIG. 12 is a diagram depicting a measured result of an imaginary part μᵣ″ of complex relative permeability and an imaginary part ∈ᵣ″ of complex relative permittivity with respect to sample 1 and sample 2;

FIG. 13 is a diagram depicting a measured result of an imaginary part ∈ᵣ″ of complex relative permittivity with respect to sample 1 and sample 3; and

FIG. 14 is an explanatory view for explaining that an electromagnetic radiation absorber of a three-dimensional continuous structure can be formed into a thin film.

### EXPLANATION OF REFERENCE NUMERAL

1, 41, 51, 61, 71 electromagnetic radiation absorber
2, 42 base material
3, 43 filler
4, 5, 6, 44, 45, 46 long hole
52 first cord-shaped member
53 second cord-shaped member

### BEST MODE FOR CARRYING OUT THE INVENTION

A detailed description of first to sixth embodiments of an electromagnetic radiation absorber and a method for absorbing electromagnetic radiation embodying the present invention will now be given by referring to the accompanying drawings.

### First Embodiment

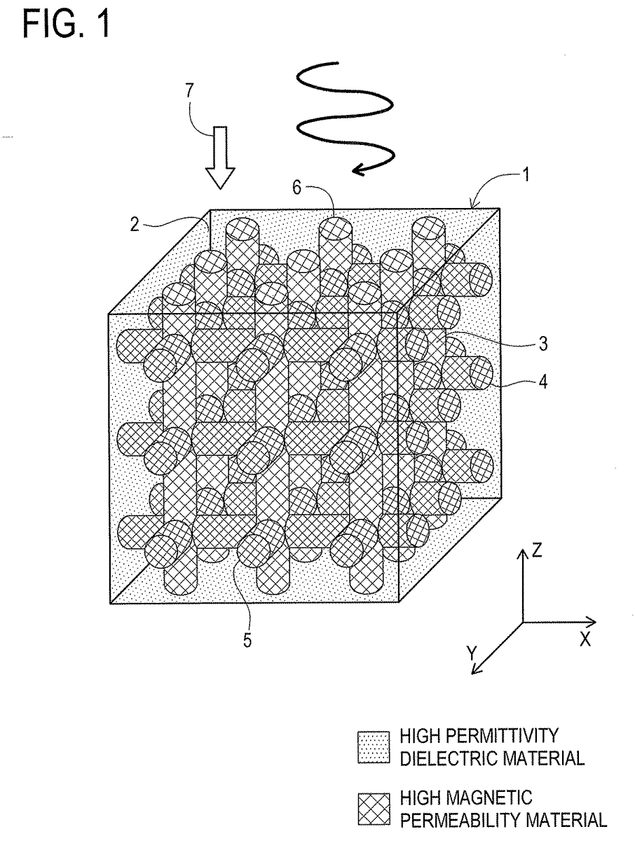

First, details of an electromagnetic radiation absorber 1 according to the first embodiment will be given while referring to FIG. 1. FIG. 1 is an explanatory view depicting the electromagnetic radiation absorber 1 according to the first embodiment.

As illustrated in FIG. 1, the electromagnetic radiation absorber 1 according to the first embodiment is configured with a composite where base material 2 formed of high permittivity dielectric material and having a cubical shape and filler 3 formed of high magnetic permeability material and having a cylindrical shape are combined. In the first embodiment, for instance, barium titanate (at measurement frequency 45 MHz, value of real part of complex relative permittivity ∈ᵣ: “90”, value of real part of complex relative permeability μᵣ: “1”) may be used as the high permittivity dielectric material. Also, as the high magnetic permeability material, for instance, ferrite (at measurement frequency 45 MHz, value of real part of complex relative permittivity ∈ᵣ: “2”, value of real part of complex relative permeability μᵣ: “90”) may be used.

Then, the electromagnetic radiation absorber 1 according to the first embodiment has a structure where high permittivity dielectric material and high magnetic permeability material are arranged in a three-dimensionally continuous manner inside the composite thereof. Here, the structure where high permittivity dielectric material and high magnetic permeability material are arranged in a three-dimensionally continuous manner means that even if the structural body (the electromagnetic radiation absorber 1 in the first embodiment) is cut at whatever location and angle, high permittivity dielectric material and high magnetic permeability material have contact with each other in a cross section thereof.

Specifically, the electromagnetic radiation absorber 1 is configured though forming long holes 4, 5 and 6, which include twenty-seven long holes in total, in three directions inside the base material 2 made of high permittivity dielectric material, and then filling each of the long holes 4, 5 and 6 with the filler 3 made of high magnetic permeability material.

Furthermore, the long holes 4, 5 and 6 include first long holes 4 formed parallel to X-axis direction of FIG. 1, second long holes 5 formed parallel to Y-axis direction, and third long holes 6 formed parallel to Z-axis direction. The long holes 4, 5 and 6 intersect with each other. In FIG. 1, the incident direction (the direction pointed by arrow 7 in FIG. 1) of the electromagnetic radiation incident on the electromagnetic radiation absorber 1 is depicted as being parallel to Z-axis, however, the incident direction is not necessarily limited to the direction parallel to the Z-axis. In addition, the filler 3 and the long holes 4, 5 and 6 are not limited to the cylindrical shape as depicted in FIG. 1, but may be formed in a polygonal column shape, etc. such as a quadrangular prism. Further, the volume ratio of high permittivity dielectric material and high magnetic permeability material of the electromagnetic radiation absorber 1 may preferably be calculated taking the values of relative permittivity and relative permeability into consideration.

Next, a detail is given on a method for manufacturing the electromagnetic radiation absorber 1 directed to the first embodiment as illustrated in FIG. 1.

Here, for manufacturing the electromagnetic radiation absorber 1, there is a method where base material 2 is firstly molded, long holes 4, 5 and 6 are then formed in the base material 2, and finally the long holes 4, 5 and 6 are filled with filler 3.

Then, the electromagnetic radiation absorber 1 manufactured in the above method has a structure where high permittivity dielectric material and high magnetic permeability material are arranged in a three-dimensionally continuous manner. There, the relative permittivity and relative permeability of the electromagnetic radiation absorber 1 manufactured in the above method never significantly decreases, compared with those of an electromagnetic radiation absorber manufactured by a method where high permittivity dielectric material and high magnetic permeability material are put into resin and mixed in particle level.

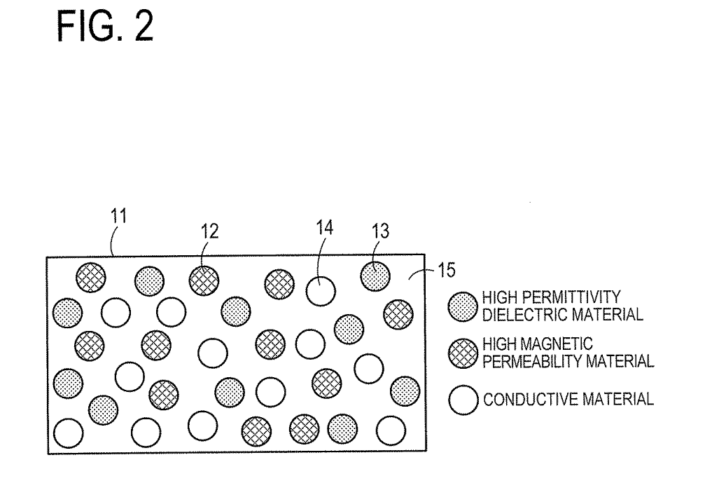

Here, FIG. 2 is a view depicting an electromagnetic radiation absorber 11 manufactured by mixing high permittivity dielectric material, high magnetic permeability material and conductive material in particle level.

As illustrated in FIG. 2, in the electromagnetic radiation absorber 11 manufactured by mixing, for instance, particles 12 of high magnetic permeability material such as ferrite, particles 13 of high permittivity dielectric material such as barium titanate and particles 14 of carbon which is conductive material into resin 15, the relative permittivity and relative permeability thereof significantly decrease from those of the high magnetic permeability material and the conductive material before mixing. For instance, in case barium titanate is used as the high permittivity dielectric material and ferrite as the high magnetic permeability material, the relative permittivity ∈ᵣ of the electromagnetic radiation absorber 11 decreases to approximately 1/100 and relative permeability μᵣ also decreases to approximately 1/100.

Accordingly, in the electromagnetic radiation absorber 11 as mixed in particle level, the refractive index decreases, and wavelength compressibility to the electromagnetic radiation penetrated inside decreases. As a result, in order to obtain an electromagnetic radiation absorbing property sufficient for an electromagnetic radiation absorbing sheet, at least a certain amount of sheet thickness is required, and it becomes difficult to make the electromagnetic radiation absorber 11 into a thin film. In contrast, the electromagnetic radiation absorber 1 as illustrated in FIG. 1 has a high electromagnetic radiation absorbing property as will be described later.

Next, the electromagnetic radiation absorbing property according to the electromagnetic radiation absorber 1 having a structure where high permittivity dielectric material and high magnetic permeability material are arranged in a three-dimensionally continuous manner as illustrated in FIG. 1 will be described.

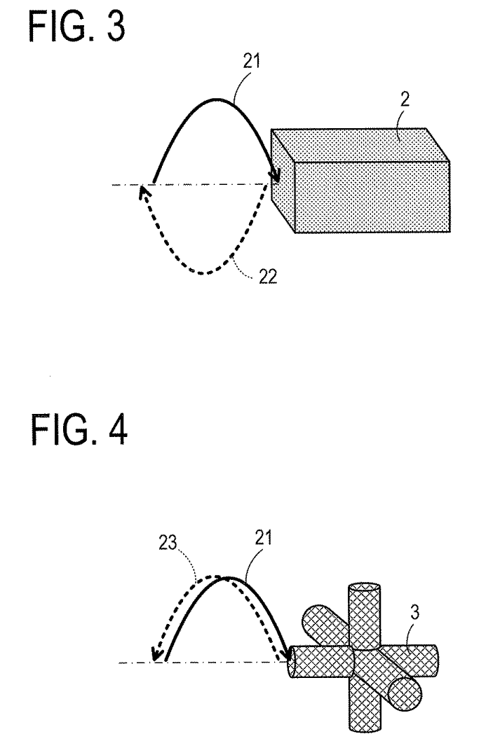

First, in FIG. 3, there are depicted an incident wave 21 when electromagnetic radiation is incident on the base material 2 (high permittivity dielectric material) included in the electromagnetic radiation absorber 1 and a reflection wave 22 reflected at the boundary thereof specifically with respect to electric field components. The following equation 1 expresses the characteristic impedance Z_{∈} of the base material 2. Equation 2 expresses coefficient of reflection Rₑ of the base material 2 on the surface of the electromagnetic radiation absorber.

$$\begin{matrix}{Z}_{ɛ} = {Z}_{0} \sqrt{\frac{1}{{ɛ}_{r}}} << {Z}_{0} & [ Equation 1 ] \\ {R}_{ɛ} = \frac{{Z}_{ɛ} - {Z}_{0}}{{Z}_{ɛ} + {Z}_{0}} \approx - 1 & [ Equation 2 ]\end{matrix}$$

Here, as expressed in equation 1, in the high permittivity dielectric material, the characteristic impedance Z_{∈} is extremely smaller than Z₀ (Z₀: characteristic impedance of air).

Then, as expressed in equation 2, the term of characteristic impedance Z_{∈} can be ignored, and the coefficient of reflection R_{∈} on the surface of the electromagnetic radiation absorber becomes approximately “−1”.

Accordingly, the waveform of the reflection wave 22 generated by the electromagnetic radiation incident on the base material 2 is approximately in antiphase with the incident wave 21.

Next, in FIG. 4, there are depicted an incident wave 21 when electromagnetic radiation is incident on the filler 3 (high magnetic permeability material) included in the electromagnetic radiation absorber 1 and a reflection wave 23 reflected at the boundary thereof specifically with respect to electric field components. The following equation 3 expresses characteristic impedance Z_{μ} of the filler 3. Equation 4 expresses coefficient of reflection R_{μ} of the filler 3 on the surface of the electromagnetic radiation absorber.

$$\begin{matrix}{Z}_{μ} = {Z}_{0} \sqrt{\frac{{μ}_{r}}{1}} >> {Z}_{0} & [ Equation 3 ] \\ {R}_{μ} = \frac{{Z}_{μ} - {Z}_{0}}{{Z}_{μ} + {Z}_{0}} \approx 1 & [ Equation 4 ]\end{matrix}$$

Here, as expressed in equation 3, in the high magnetic permeability material, the characteristic impedance Z_{μ} is extremely larger than Z₀.

Then, as expressed in equation 4, the item of characteristic impedance Z₀ of air can be ignored, and the coefficient of reflection R_{μ} on the surface of the electromagnetic radiation absorber becomes approximately “1”.

Accordingly, the waveform of the reflection wave 23 generated by the electromagnetic radiation incident on the filler 3 straight from an opening is approximately in phase with the incident wave 21.

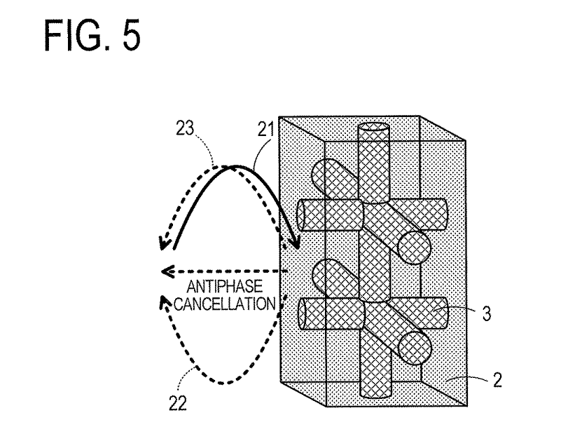

Next, in FIG. 5, there are depicted an incident wave 21 and reflection waves 22 and 23, specifically with respect to electric field components when electromagnetic radiation is incident on the electromagnetic radiation absorber 1 directed to the first embodiment having a (0024) structure where base material 2 (high permittivity dielectric material) and filler 3 (high magnetic permeability material) are combined and respectively arranged in a three-dimensionally continuous manner.

As above mentioned, the waveform of the reflection wave 22 from the base material 2 is approximately in antiphase with the incident wave 21 and the waveform of the reflection wave 23 from the filler 3 is approximately in phase with the incident wave 21, so that the reflection wave 22 and the reflection wave 23 are in antiphase with each other, and thus cancel out each other. Specifically with respect to magnetic field components of the incident wave and of the reflection wave when the electromagnetic radiation is incident, the reflection wave from the base material 2 and the reflection wave 23 from the filler 3 are also in antiphase with each other, and thus cancel out each other, which is not shown in the drawings.

Accordingly, the electromagnetic radiation absorber 1 can greatly attenuate the reflection wave reflected from the surface thereof. The electromagnetic radiation absorber 1 can also utilize high permittivity dielectric material without lowering relative permittivity ∈ᵣ thereof and high magnetic permeability material without lowering relative permeability μᵣ thereof. As a result, the electromagnetic radiation absorber 1 can obtain high refractive index. Accordingly, even if made into a sheet which is thin with respect to the incident direction of the electromagnetic radiation, it is possible for the electromagnetic radiation absorber 1 to attenuate the electromagnetic radiation and to sufficiently decrease the wavelength thereof.

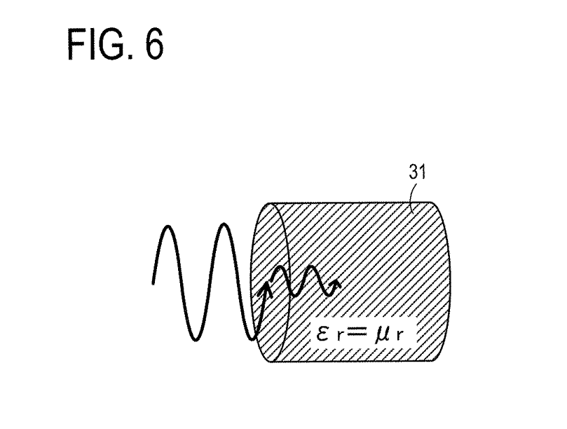

Meanwhile, with respect to the electromagnetic radiation of low frequency (MHz band), such an electromagnetic radiation absorber where high permittivity dielectric material and high magnetic permeability material are densely combined as the electromagnetic radiation absorber 1 according to the first embodiment can be regarded as the same as an electromagnetic radiation absorber 31 which is formed of homogeneous material having high permittivity and high permeability as illustrated in FIG. 6.

Accordingly, in case where the value of real part of relative permittivity ∈ᵣ of the base material 2 (high permittivity dielectric material) is equal to the value of real part of relative permeability μᵣ of the filler 3 (high magnetic permeability material) and the value of imaginary part of relative permittivity ∈ᵣ of the base material 2 is equal to the value of imaginary part of relative permeability of the filler 3, the characteristic impedance of the electromagnetic radiation absorber 31 becomes equal to the characteristic impedance of air, as expressed in the following equation 5.

$${Z}_{ɛ = μ} = {Z}_{0} \sqrt{\frac{{μ}_{r}}{{ɛ}_{r}}} = {Z}_{0} \qquad [ Equation 5 ]$$

Accordingly, the incident electromagnetic radiation will not reflect on the surface of the electromagnetic radiation absorber 31, but can entirely be made to enter the electromagnetic radiation absorber 31. Further, the refractive index of the electromagnetic radiation absorber 31 becomes very high so that even if made into a sheet which is thin with respect to the incident direction of the electromagnetic radiation, it is possible for the electromagnetic radiation absorber 31 to attenuate the electromagnetic radiation and to sufficiently decrease the wavelength thereof.

As has been described above, in the electromagnetic radiation absorber 1 according to the first embodiment, a composite where high permittivity dielectric material and high magnetic permeability material are arranged in a three-dimensionally continuous manner can be made in a simple structure. Accordingly, manufacture thereof becomes easy and excellent productivity thereof is ensured. In addition, making high permittivity dielectric material and high magnetic permeability material continue three-dimensionally to form a composite structure, the high permittivity dielectric material and the high magnetic permeability material continue also with respect to a direction of oscillation of the electric field components and the magnetic field components of the electromagnetic radiation. Thus, a magnetic circuit and an electric circuit thereof will not be disrupted. Accordingly, the electromagnetic radiation absorber 1 has a high electromagnetic radiation absorbing property with respect to electromagnetic radiation of wideband frequencies including electromagnetic radiation of low frequency without significant decrease of relative permittivity ∈ᵣ and relative permeability μᵣ. Further, even when the electromagnetic radiation absorber 1 is made into a thin sheet, the sheet still maintains the high electromagnetic radiation absorbing property. Accordingly the electromagnetic radiation absorber 1 can be used for wider purposes.

### Second Embodiment

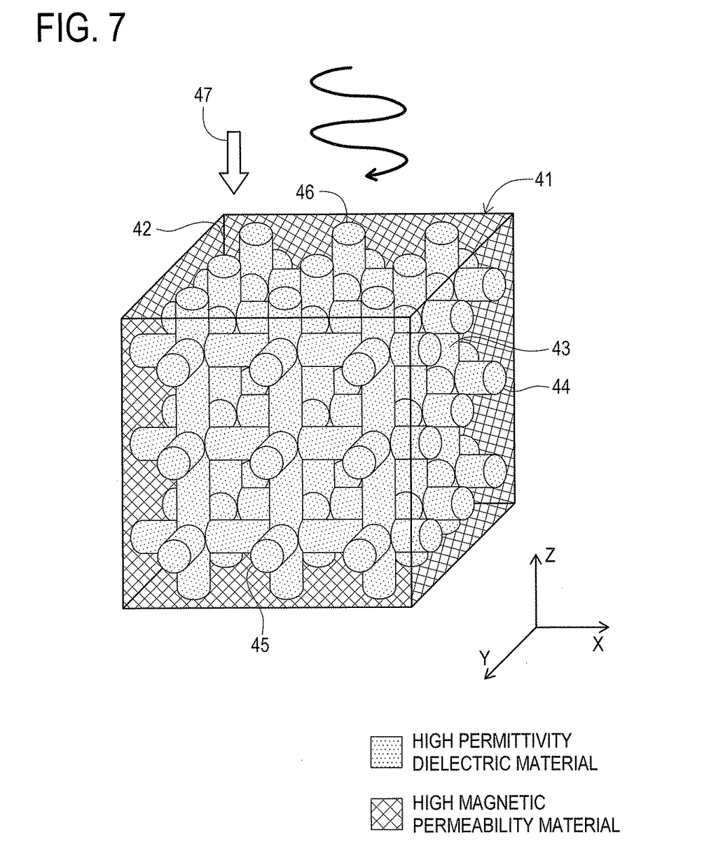

Next, details of an electromagnetic radiation absorber 41 according to the second embodiment will be given while referring to FIG. 7. FIG. 7 is an explanatory view depicting the electromagnetic radiation absorber 41 according to the second embodiment.

As illustrated in FIG. 7, the electromagnetic radiation absorber 41 according to the second embodiment is configured with a composite where base material 42 formed of high magnetic permeability material and having a cubical shape and filler 43 formed of high permittivity dielectric material and having a cylindrical shape are combined. In the second embodiment, for instance, ferrite (at measurement frequency 45 MHz, value of real part of complex relative permittivity ∈ᵣ: “2”, value of real part of complex relative permeability μᵣ: “90”) may be used as the high magnetic permeability material. Also, as the high permittivity dielectric material, for instance, water (at measurement frequency 45 MHz, value of real part of complex relative permittivity ∈ᵣ: “80.4”, value of real part of complex relative permeability μᵣ: “1”) may be used. However, when water is used as the filler 43, it is preferable to use a gel-like body where water is absorbed into such material having a high water-absorbing property and a high water-retention capacity as agar or sodium polyacrylate.

The following are possible combinations of the base material 42 and the filler 43:

(a) the base material 42 of “porous ferrite” and the filler 43 of “conductive gel (gel-like body with electrolyte such as NaCl dissolved therein)”; and
(b) the base material 42 of “porous ferrite” and the filler 43 of “BaTiO₃ with conductive filler kneaded therein”.

Then, the electromagnetic radiation absorber 41 according to the second embodiment has a structure where high permittivity dielectric material and high magnetic permeability material are arranged in a three-dimensionally continuous manner inside the composite thereof, as well as the first embodiment. Specifically, the electromagnetic radiation absorber 41 is configured though forming long holes 44, 45 and 46, which include twenty-seven long holes in total, in three directions inside the base material 42 made of high magnetic permeability material, and then filling each of the long holes 44, 45 and 46 with the filler 43 made of high permittivity dielectric material.

Furthermore, the long holes 44, 45 and 46 include first long holes 44 formed parallel to X-axis direction of FIG. 7, second long holes 45 formed parallel to Y-axis direction, and third long holes 46 formed parallel to Z-axis direction, and intersect with each other. In FIG. 7, the incident direction (the direction pointed by arrow 47 in FIG. 7) of the electromagnetic radiation incident on the electromagnetic radiation absorber 41 is depicted as being parallel to Z-axis, however, the incident direction is not necessarily limited to the direction parallel to the Z-axis. In addition, the filler 43 and the long holes 44, 45 and 46 are not limited to the cylindrical shape as depicted in FIG. 7, but may be formed in a polygonal column shape, etc. such as a quadrangular prism. Further, the volume ratio of high permittivity dielectric material and high magnetic permeability material of the electromagnetic radiation absorber 41 may preferably be calculated taking the values of relative permittivity and relative permeability into consideration.

Next, a detail is given on a method for manufacturing the electromagnetic radiation absorber 41 directed to the second embodiment as illustrated in FIG. 7.

Here, for manufacturing the electromagnetic radiation absorber 41, there is a method where base material 42 is firstly molded, long holes 44, 45 and 46 are then formed in the base material 42, and finally the long holes 44, 45 and 46 are filled with filler 43.

In the above electromagnetic radiation absorber 41 according to the second embodiment, a composite where high permittivity dielectric material and high magnetic permeability material are arranged in a three-dimensionally continuous manner can be made in a simple structure. Accordingly, manufacture thereof becomes easy and excellent productivity thereof is ensured. In addition, through making high permittivity dielectric material and high magnetic permeability material continue three-dimensionally to form a composite structure, the high permittivity dielectric material and the high magnetic permeability material continue also with respect to a direction of oscillation of the electric field components and the magnetic field components of the electromagnetic radiation. Thus, a magnetic circuit and an electric circuit thereof will not be disrupted. Accordingly, relative permittivity ∈ᵣ and relative permeability μᵣ of the electromagnetic radiation absorber 41 never significantly decrease. Further, the electromagnetic radiation absorber 41 has a high electromagnetic radiation absorbing property with respect to electromagnetic radiation of wideband frequencies including electromagnetic radiation of low frequency as well as the electromagnetic radiation absorber 1 according to the first embodiment already illustrated in FIGS. 3 to 6. In addition, even when the electromagnetic radiation absorber 41 is made into a thin sheet, the sheet still maintains the high electromagnetic radiation absorbing property. Accordingly the electromagnetic radiation absorber 41 can be used for wider purposes.

### Third Embodiment

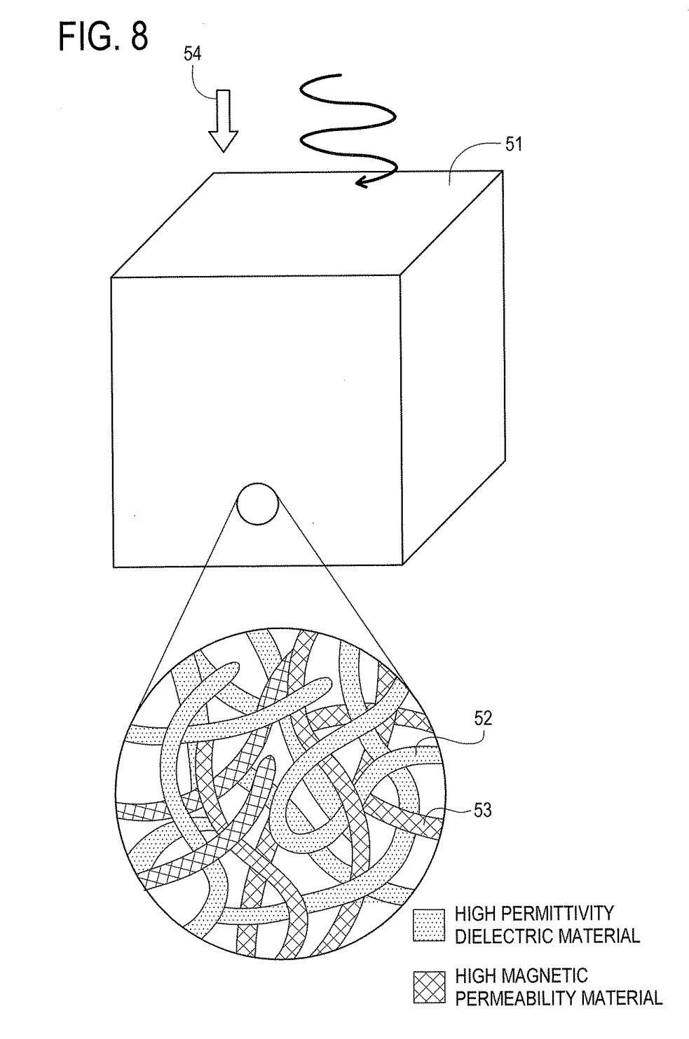

Next, details of an electromagnetic radiation absorber 51 according to the third embodiment will be given while referring to FIG. 8. FIG. 8 is an explanatory view depicting an electromagnetic radiation absorber 51 according to the third embodiment with a partial enlargement.

As illustrated in FIG. 8, the electromagnetic radiation absorber 51 according to the third embodiment is configured with a composite where first cord-shaped members 52 formed of high permittivity dielectric material and second cord-shaped members 53 formed of high magnetic permeability material are combined. In the third embodiment, for instance, barium titanate (at measurement frequency 45 MHz, value of real part of complex relative permittivity ∈ᵣ: “90”, value of real part of complex relative permeability μᵣ: “1”) or water (at measurement frequency 45 MHz, value of real part of complex relative permittivity ∈ᵣ: “80.4”, value of real part of complex relative permeability μᵣ: “1”) may be used as high permittivity dielectric material. Also, as high magnetic permeability material, for instance, ferrite (at measurement frequency 45 MHz, value of real part of complex relative permittivity ∈ᵣ: “2”, value of real part of complex relative permeability μᵣ: “90”) may be used. However, specifically when water is used as the second cord-shaped member 53, it is preferable to use a gel-like body where water is absorbed into such material having a high water-absorbing property and a high water-retention capacity as agar or sodium polyacrylate.

Then, the electromagnetic radiation absorber 51 according to the second embodiment has a structure where high permittivity dielectric material and high magnetic permeability material are arranged in a three-dimensionally continuous manner inside the composite thereof, as well as the first embodiment. Specifically, the electromagnetic radiation absorber 51 is configured though fixing the first cord-shaped members 52 and the second cord-shaped members 53 in a state intertwined three-dimensionally with each other. Further, the volume ratio of high permittivity dielectric material and high magnetic permeability material of the electromagnetic radiation absorber 51 may preferably be calculated taking the values of relative permittivity and relative permeability into consideration.

In the above electromagnetic radiation absorber 51 according to the third embodiment, a composite where high permittivity dielectric material and high magnetic permeability material are arranged in a three-dimensionally continuous manner can be made in a simple structure. In addition, the high permittivity dielectric material and the high magnetic permeability material continue also in a direction of oscillation of the electric field components and the magnetic field components of the electromagnetic radiation, so that the magnetic circuit and the electric circuit thereof will not be disrupted. Thus, relative permittivity ∈ᵣ and relative permeability μᵣ of the electromagnetic radiation absorber 51 never significantly decrease. Further, the electromagnetic radiation absorber 51 has a high electromagnetic radiation absorbing property with respect to electromagnetic radiation of wideband frequencies including electromagnetic radiation of low frequency as well as the electromagnetic radiation absorber 1 according to the first embodiment already illustrated in FIGS. 3 to 6. In addition, even when the electromagnetic radiation absorber 51 is made into a thin sheet, the sheet still maintains high electromagnetic radiation absorbing property. Accordingly the electromagnetic radiation absorber 51 can be used for wider purposes.

### Fourth and Fifth Embodiment

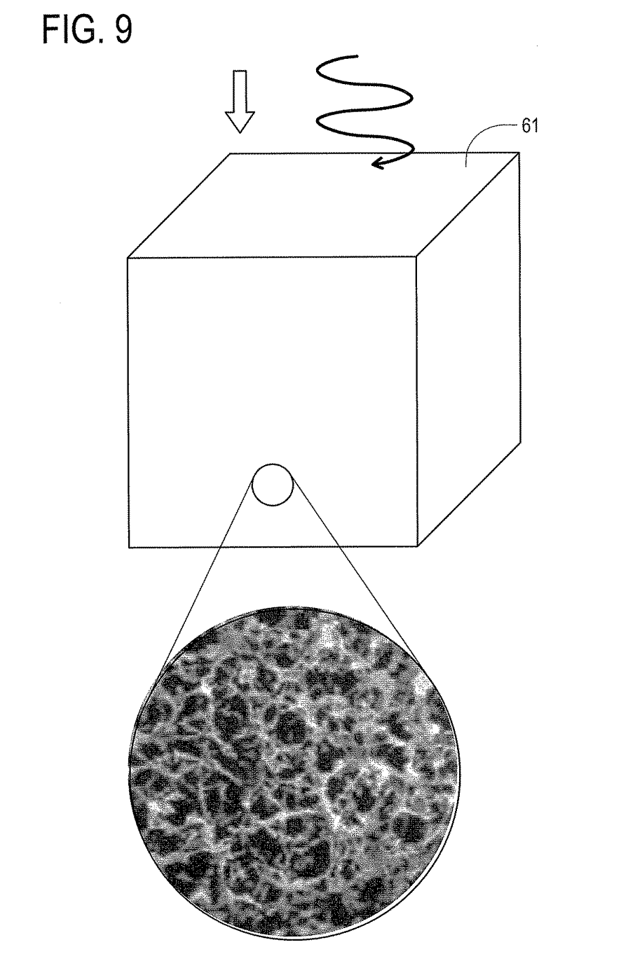

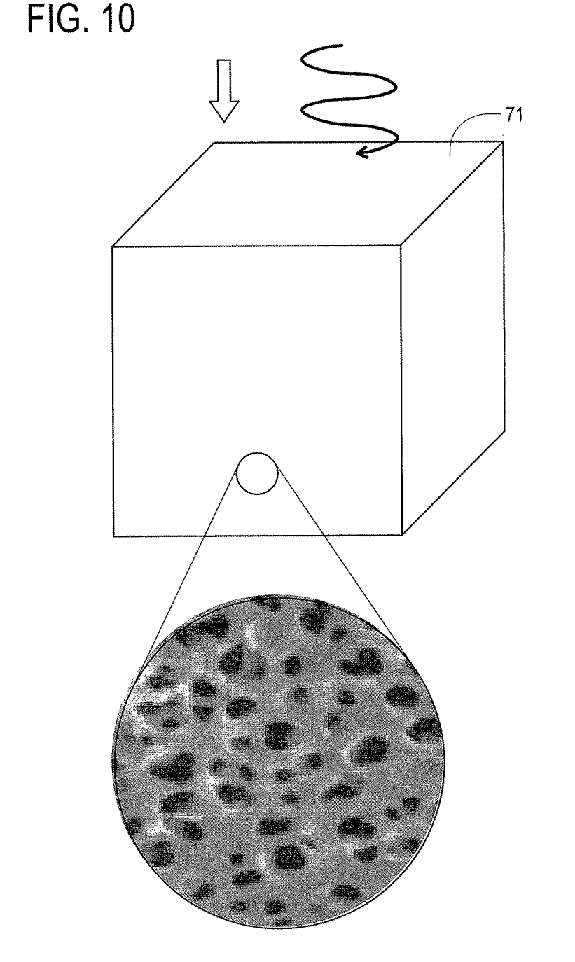

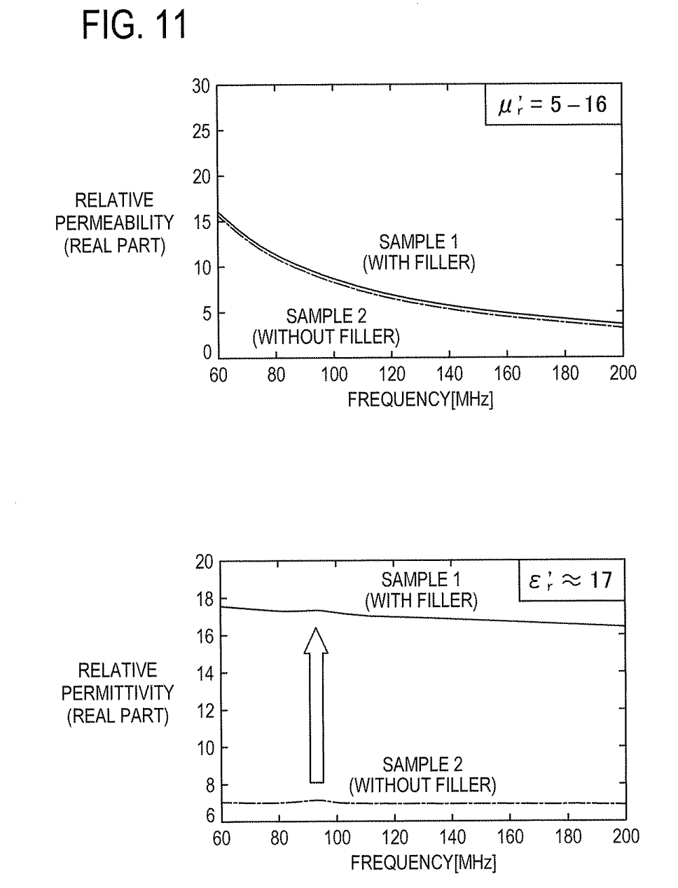

Next, details of electromagnetic radiation absorbers 61 and 71 according to the fourth and fifth embodiments will be given while referring to FIGS. 9 and 10. FIG. 9 is an explanatory view depicting an electromagnetic radiation absorber 61 according to the fourth embodiment with a partial enlargement, and FIG. 10 is an explanatory view depicting an electromagnetic radiation absorber 71 according to the fifth embodiment with a partial enlargement.

As illustrated in FIG. 9, the electromagnetic radiation absorber 61 according to the fourth embodiment is configured with a composite where high permittivity dielectric material and high magnetic permeability material are combined. As illustrated in FIG. 10, the electromagnetic radiation absorber 71 according to the fifth embodiment is likewise configured with a composite where high permittivity dielectric material and high magnetic permeability material are combined.

In the fourth and fifth embodiments, for instance, barium titanate (at measurement frequency 45 MHz, value of real part of complex relative permittivity ∈ᵣ: “90”, value of real part of complex relative permeability μᵣ: “1”) or water (at measurement frequency 45 MHz, value of real part of complex relative permittivity ∈ᵣ: “80.4”, value of real part of complex relative permeability μᵣ: “1”) may be used as high permittivity dielectric material. Also, as high magnetic permeability material, for instance, ferrite (at measurement frequency 45 MHz, value of real part of complex relative permittivity ∈ᵣ: “2”, value of real part of complex relative permeability μᵣ: “90”) may be used. However, specifically when water is used as high permittivity dielectric material, it is preferable to use a gel-like body where water is absorbed to such material having a high water-absorbing property and a water-retention capacity as agar or sodium polyacrylate.

Then, the electromagnetic radiation absorbers 61 and 71 according respectively to the fourth and fifth embodiments have a structure where high permittivity dielectric material and high magnetic permeability material are arranged in a three-dimensionally continuous manner inside the composite thereof, as well as the first embodiment.

In addition, each of the electromagnetic radiation absorber 61 and the electromagnetic radiation absorber 71 has a space continuously connected in a three-dimensional net-like form. Accordingly, specifically when water is used as the high permittivity dielectric material, through filling the space with water, a structure can be obtained where high permittivity dielectric material continues three-dimensionally.

In the above electromagnetic radiation absorber 61 according to the fourth embodiment and electromagnetic radiation absorber 71 according to the fifth embodiment, a composite where high permittivity dielectric material and high magnetic permeability material are arranged in a three-dimensionally continuous manner can be formed in a simple structure, thereby the high permittivity dielectric material and the high magnetic permeability material continue also in a direction of oscillation of the electric field components and the magnetic field components of the electromagnetic radiation, so that the magnetic circuit and the electric circuit thereof will not be disrupted. Thus, relative permittivity ∈ᵣ and relative permeability μᵣ of the electromagnetic radiation absorber 61 or 71 never significantly decrease. Further, the electromagnetic radiation absorber 61 or 71 has a high electromagnetic radiation absorbing property with respect to electromagnetic radiation of wideband frequencies including electromagnetic radiation of low frequency as well as the electromagnetic radiation absorber 1 according to the first embodiment illustrated in FIGS. 3 to 6. In addition, even when the electromagnetic radiation absorber 61 or 71 is made into a thin sheet, the sheet still maintains high electromagnetic radiation absorbing property. Accordingly the electromagnetic radiation absorber 61 or 71 can be used for wider purposes.

### Sixth Embodiment

Next, an electromagnetic radiation absorber according to a sixth embodiment will be described while referring to FIGS. 11 to 14. An electromagnetic radiation absorber according to the sixth embodiment performs matching between the real parts of complex relative permittivity and complex relative permeability and matching between the imaginary parts of complex relative permittivity and complex relative permeability, and thereby matches the characteristic impedance of the electromagnetic radiation absorber to the characteristic impedance of air.

As described above, the electromagnetic radiation absorbers according to the first to fifth embodiments are each composed of plural kinds of material, that is, high permittivity dielectric material and high magnetic permeability material. However, with respect to electromagnetic radiation of low frequency (MHz band), these electromagnetic radiation absorbers can be regarded as the same as an electromagnetic radiation absorber which is formed of homogeneous material having high permittivity and permeability.

In this case, by matching the characteristic impedance of such an electromagnetic radiation absorber to the characteristic impedance of air, it is possible to make all of incident electromagnetic wave enter the electromagnetic radiation absorber without reflecting from the surface of the electromagnetic radiation absorber.

In order to perform matching of the impedances as mentioned above, conditions (A) and (B) must be satisfied in the following equation 6:

$$\dot{Z} = {Z}_{0} \sqrt{\frac{{μ}_{r}^{′} - j {μ}_{r}^{″}}{{ɛ}_{r}^{′} - j ( {ɛ}_{r}^{″} + \frac{σ}{ω} )}} \qquad [ Equation 6 ]$$

(A) The real term (real part of complex relative permeability) μᵣ′ of the numerator and the real term (real part of complex relative permittivity) ∈ᵣ′ of the denominator are of equal value (refer to equation 7).

(B) The imaginary term (imaginary part of complex relative permeability) μᵣ″ of the numerator and the imaginary term (term including imaginary part ∈ᵣ″ of complex relative permittivity) ∈ᵣ″+σ/ω oho of the denominator are of equal value (refer to equation 7).

$$( \begin{matrix}{μ}_{r}^{′} = {ɛ}_{r}^{′} \\ {μ}_{r}^{″} = {ɛ}_{r}^{″} + \frac{σ}{ω}\end{matrix} \qquad [ Equation 7 ]$$

Next, by using the measurement results of samples 1 to 3, there will be explained how the condition is satisfied for establishing matching between the real parts of complex relative permeability and complex relative permittivity and matching between the imaginary parts of complex relative permeability and complex relative permittivity of an electromagnetic radiation absorber.

(Sample 1 and Sample 2 Subject to Measurement)

An electromagnetic radiation absorber configured in the same manner as the electromagnetic radiation absorber 41 of the second embodiment was used as sample 1 for measurement. However, ferrite was used as the base material 42 of this electromagnetic radiation absorber. Also, BaTiO₃ treated with Au colloid was used as filler 43.

To be more precise, sample 1 was produced by the following steps (a) to (e):

(a) wet-grinding BaTiO₃ by using ULTRA APEX MILL, in which 1-propanol was used as solvent, quantity ratio of the BaTiO₃ and the solvent was set to 1:3, and grinding time was set to 20 minutes;

(b) removing the solvent after completion of grinding;

(c) producing Au nanocolloid, more specifically, by reducing HAuCl₄.4H₂O with trisodium citrate water solution (80° C.×30 min);

(d) adding the ground BaTiO₃ into thus-produced Au nanocolloid solution and mix them;

(e) repeating cleaning and centrifuging, and then drying to thereby produce BaTiO₃ treated with Au colloid;

(f) producing slurry by combining thus-produced BaTiO₃ treated with Au colloid, cyanoethyl pullulan and N-methylpyrrolidone (NMP) in a weight ratio of 100:10:50; and

(g) filling with the slurry the long holes 44, 45 and 46 formed in the base material 42 made of ferrite, and thereby forming filler 43, in the similar manners to the first to sixth steps described in the first embodiment.

In the above-described manners, an electromagnetic radiation absorber was produced to be used for sample 1.

As a comparative example, there was also produced sample 2 solely composed of base material 42 and not filled with a dielectric (BaTiO₃ treated with Au colloid).

(Sample Measurement 1)

After measuring the real part μᵣ′ of complex relative permeability and the real part ∈ᵣ′ of complex relative permittivity with respect to the above-described sample 1, the result was obtained as indicated in FIG. 11. For the purpose of comparison, FIG. 11 depicts the measurement result by sample 2 not filled with a dielectric (BaTiO₃ treated with Au colloid). Measurement frequency ranged from 60 MHz to 200 MHz.

As indicated in FIG. 11, the real part μᵣ′ of complex relative permeability of sample 1 changed within the range between 5 and 12 (μᵣ′=5-12) with respect to the measurement frequency. Meanwhile, the real part ∈ᵣ′ of complex relative permittivity of sample 1 did not depend on the measurement frequency and stood at a substantially fixed value. It is to be noted that the real part ∈ᵣ′ of complex relative permittivity of sample 2 not filled with the dielectric was approximately equal to 7 (∈ᵣ′≈7) while the real part ∈ᵣ′ of complex relative permittivity of sample 1 filled with the dielectric increased to the value approximately equal to 17 (∈ᵣ′≈17).

Thus, the comparison between the measurement results indicated in FIG. 11 reveals that it is possible to control the value of the real part ∈ᵣ′ of complex relative permittivity by filling a dielectric into the base material 42. In other words, it is possible to set the real part μᵣ′ of complex relative permeability and the real part ∈ᵣ′ of complex relative permittivity to an equal value by adjusting material constants and a design value of filling factor of the dielectric.

(Sample Measurement 2)

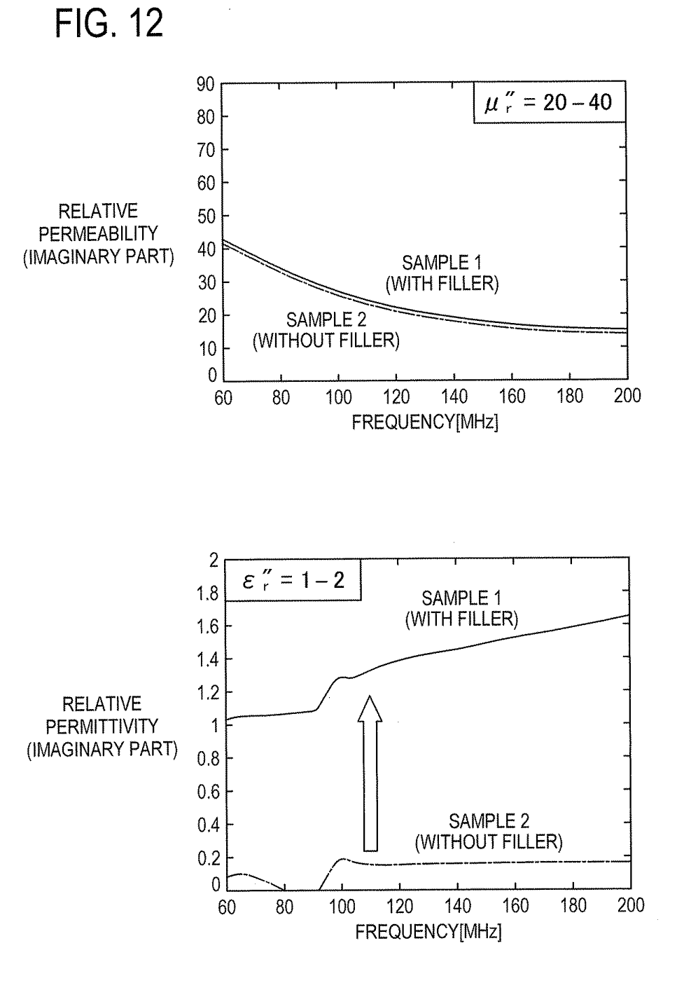

Next, after measuring the imaginary part μᵣ″ of complex relative permeability and the imaginary part ∈ᵣ″ of complex relative permittivity with respect to the above-described sample 1, the result was obtained as indicated in FIG. 12. For the purpose of comparison, FIG. 12 depicts the measurement result by sample 2 not filled with the dielectric (BaTiO₃ treated with Au colloid). Measurement frequency ranged from 60 MHz to 200 MHz.

As indicated in FIG. 12, the imaginary part μᵣ′ of complex relative permeability of sample 1 changed within the range between 20 and 40 (μᵣ″=20-40) with respect to the measurement frequency. Meanwhile, the imaginary part ∈ᵣ″ of complex relative permittivity of sample 2 not filled with dielectric ranged between 0 and 0.2 (∈r″=0-0.2), while the imaginary part ∈ᵣ″ of complex relative permittivity of sample 1 filled with the dielectric increased to the value ranging between 1 and 2 (∈ᵣ″=1-2).

Thus, comparing the measurement results indicated in FIG. 12, the imaginary part ∈ᵣ″ of complex relative permittivity is extremely small compared with the imaginary part μᵣ″ of complex relative permeability, even if the sample is filled with the dielectric. Therefore, it can be seen that the imaginary part ∈ᵣ″ of complex relative permittivity must be increased further in order to set the imaginary part μᵣ″ of complex relative permeability and the term (∈ᵣ″+σ/ω) including the imaginary part of complex relative permittivity to the equal value.

(Sample 3 Subject to Measurement)

As sample 3 (electromagnetic radiation absorber according to the sixth embodiment) used for measurement, an electromagnetic radiation absorber was used which was configured in the same manner as the electromagnetic radiation absorber 41 according to the second embodiment, similarly to sample 1. Ferrite was used as the base material 42 of this electromagnetic radiation absorber. Also, as filler 43, there was used a material made by adding conductive material (such as Ag) to BaTiO₃ treated with Au colloid.

Detailed description on steps for producing sample 3 will be omitted here, since the steps are the same as those for producing sample 1, except the step of adding Ag to slurry.

(Sample Measurement 3)

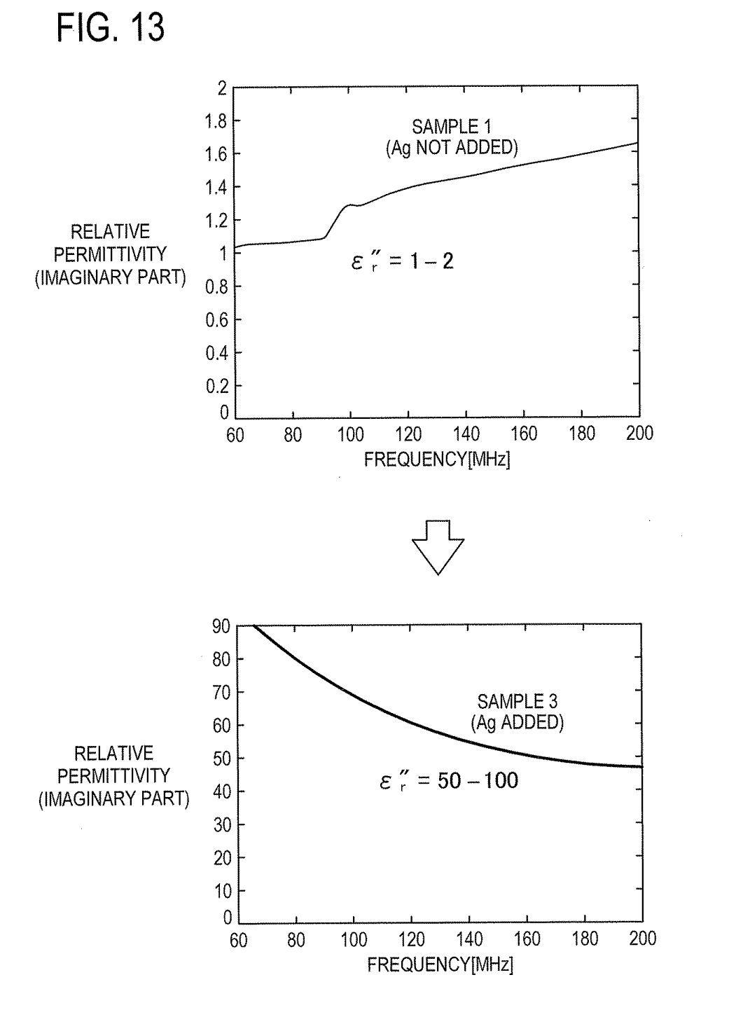

Next, after measuring the imaginary part ∈ᵣ″ of complex relative permittivity with respect to the above-described sample 3, the result was obtained as indicated in FIG. 13. For the purpose of comparison, FIG. 13 depicts the measurement result of sample 1, in which Ag was not added to its dielectric. Measurement frequency ranged from 60 MHz to 200 MHz.

FIG. 13 shows that, with respect to sample 1 in which Ag was not added to its dielectric, the measured value of the imaginary part ∈ᵣ″ of complex relative permittivity ranged between 1 and 2 (∈ᵣ″=1-2) as described above. On the other hand, with respect to sample 3 in which Ag was added to its dielectric, the value of the imaginary part ∈ᵣ″ of complex relative permittivity increased to the value ranging between 50 and 100 (∈ᵣ″=50-100).

Thus, the comparison between the measurement results indicated in FIG. 13 reveals that it is possible to increase greatly and control the value of imaginary part ∈ᵣ″ of complex relative permittivity by adding conductive material (such as Ag) to a dielectric which fills in the long holes 44, 45 and 46. In other words, by adjusting a kind and an adding amount of conductive material to be added, the imaginary part μᵣ″ of complex relative permeability can be made equal to the term (∈ᵣ″+σ/ω) including the imaginary part of complex relative permittivity.

As a result, it is possible to match the characteristic impedance of the electromagnetic radiation absorber to the characteristic impedance of air. This makes it possible to make all of incident electromagnetic wave enter the electromagnetic radiation absorber without reflecting from the surface of the electromagnetic radiation absorber.

The foregoing has described an embodiment of using as a sample an electromagnetic radiation absorber which was configured in the same manner as the electromagnetic radiation absorber 41 according to the second embodiment. It is to be noted that similar result can be obtained if electromagnetic radiation absorbers each configured in the same manner as the electromagnetic radiation absorbers according to the first, and third to fifth embodiments.

This means that it is possible to increase greatly and control the value of imaginary part of complex relative permittivity of an electromagnetic radiation absorber by adding conductive material to high permittivity dielectric material. Therefore, by adjusting a kind and an adding amount of conductive material to be added, it is possible to set the imaginary part μᵣ″ of complex relative permeability to an equal value as the term (∈ᵣ″+σ/ω) including the imaginary part of complex relative permittivity. Accordingly, it is possible to match the characteristic impedance of an electromagnetic radiation absorber to the characteristic impedance of air.

The present invention is not limited to the above-described embodiments, and it is obvious that various improvements and modifications can be made thereto without departing from the scope of the present invention.

For instance, in the first and second embodiments, there are formed nine long holes per direction in the respective base materials 2 and 42. However, the number of these long holes per direction may be more than or less than nine. Also, materials other than the materials as mentioned in the above embodiments may be used as the high permittivity dielectric material and the high magnetic permeability material.

Further, even when an electromagnetic radiation absorber having a three-dimensionally continuous structure as aforementioned in the first to sixth embodiments, in which high permittivity dielectric material and high magnetic permeability continue three-dimensionally, is made into a thin sheet, the sheet still maintains a high electromagnetic absorbing property. This is explained by the theoretical equations which will be described in the following.

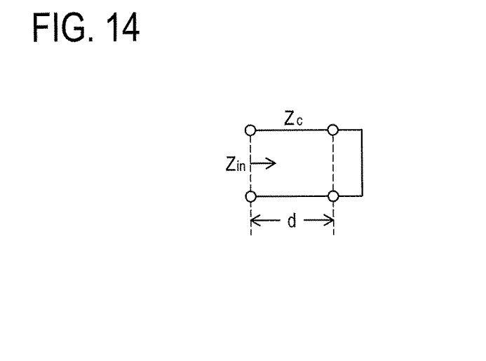

The characteristic impedance Zᵢₙ in the surface of an electromagnetic radiation absorber is given by equation 8 when represented by a distributed constant circuit as illustrated in FIG. 14. It is to be noted that equation 8 applies to a case where a metal plate and the like is placed at the back side of the electromagnetic radiation absorber with respect to an incident direction of electronic magnetic radiation and the circuit is shorted with the metal plate.

$${Z}_{in} = {Z}_{o} \sqrt{\frac{{μ}_{r}}{{ɛ}_{r}}} tan h ( j \frac{2 π d}{λ} \sqrt{{μ}_{r} {ɛ}_{r}} ) \qquad [ Equation 8 ]$$

Here, the complex relative permeability of the electromagnetic radiation absorber is defined as μᵣ(=μᵣ′−jμᵣ″) and the complex relative permittivity is defined as ∈ᵣ(=∈ᵣ′−j∈ᵣ″).

Then, under the assumption that impedance matching has been performed, the relative permittivity μᵣ and the relative magnetic permeability pr have an equal value (that is, if μᵣ′−jμᵣ″=∈ᵣ′−j∈ᵣ″, then μᵣ′=∈ᵣ′ and μᵣ″=∈ᵣ″) and at the same time the characteristic impedance Zᵢₙ of the electromagnetic radiation absorber and the characteristic impedance Z₀ of air have an equal value (that is, Zᵢₙ=Z₀). Taking this condition into consideration, formula 9 is derived from formula 8.

$$1 = tan h ( j \frac{2 π d}{λ} {ɛ}_{r} ) \qquad [ Equation 9 ]$$

Further, substituting ∈ᵣ=∈ᵣ′−j∈ᵣ″ into equation 9 yields formula 10.

$$1 = tan h ( \frac{2 π d}{λ} {ɛ}_{r}^{″} + j \frac{2 π d}{λ} {ɛ}_{r}^{′} ) \qquad [ Equation 10 ]$$

Further, equation 11 is derived by expanding tanh θ in equation 10.

$${e}^{- \frac{2 π d}{λ} {ɛ}_{r}^{″}} \times {e}^{- j \frac{2 π d}{λ} {ɛ}_{r}^{′}} = 0 \qquad [ Equation 11 ]$$

Taking notice of attenuation term, equation 12 is established in order to satisfy equation 11.

$${e}^{- \frac{2 π d}{λ} {ɛ}_{r}^{″}} = 0 \qquad [ Equation 12 ]$$

Here, given that the frequency f of incident wave is 300 MHz (f=300 MHz) (wavelength λ=1.0 m), when the thickness of a sheet d is 20 mm (d=20 mm), the values of the attenuation term with respect to ∈ᵣ″ as indicated in the equation 12 are obtained as indicated in table 1.

TABLE 1

| εᵣ″ | ${e}^{- \frac{2 π d}{λ} {ɛ}_{r}^{″}}$ |
|---|---|
| 20 | 0.81 × 10⁻¹ |
| 40 | 0.65 × 10⁻² |
| 60 | 0.53 × 10⁻³ |

For instance, if the value of imaginary part ∈ᵣ″ of complex relative permeability is 40 (∈ᵣ″=40), the attenuation term has the value of 0.65×10⁻² as indicated in table 1. This means that the electromagnetic radiation absorber brings about the attenuation effect of 87.38 dB. Therefore, when using an electromagnetic radiation absorber of which imaginary part ∈ᵣ″ of complex relative permeability has the value of, for instance, 40 (∈ᵣ″=40), a sheet with thickness of 20 mm absorbs electromagnetic radiation with frequency f of 300 MHz (f=300 MHz) (wavelength λ=1.0 m) by an amount of 87.38 db.

1. An electromagnetic radiation absorber comprising:
a composite of high permittivity dielectric material and high magnetic permeability material,
wherein, in the composite, the high permittivity dielectric material and the high magnetic permeability material are arranged in a three-dimensionally continuous manner.

2. The electromagnetic radiation absorber according to claim 1, further comprising:
base material made up of one of the high permittivity dielectric material and the high magnetic permeability material, the base material including therein a plurality of long holes; and
filler made up of other one of the high permittivity dielectric material and the high magnetic permeability material, the filler being configured to fill in the plurality of long holes,
wherein the plurality of long holes include:
a first long hole formed in a predetermined direction;
a second long hole intersecting with the first long hole; and
a third long hole intersecting with the first long hole and the second long hole.

3. The electromagnetic radiation absorber according to claim 1, further comprising:
a first cord-shaped member formed of the high permittivity dielectric material; and
a second cord-shaped member formed of the high magnetic permeability material,
wherein plurality of the first cord-shaped member and plurality of the second cord-shaped member are intermingled.

4. The electromagnetic radiation absorber according to claim 1, wherein conductive material is added to the high permittivity dielectric material.

5. An electromagnetic radiation absorbing method for absorbing electromagnetic radiation incident on the high permittivity dielectric material and the high magnetic permeability material, the method utilizing an electromagnetic radiation absorber including high permittivity dielectric material and high magnetic permeability material, the method comprising:
bringing a first reflection wave that is reflection of the electromagnetic radiation incident on the high permittivity dielectric material and a second reflection wave that is reflection of the electromagnetic radiation incident on the high magnetic permeability material into opposite phase to each other, thereby cancelling out the first reflection wave and the second reflection wave.
